(19) United States
(12) Patent Application Publication
(10) Pub. No.: US 2009/0061623 A1
(43) Pub. Date: Mar. 5, 2009

(54) METHOD OF FORMING ELECTRICAL CONNECTION STRUCTURE

(75) Inventors: Yu-Lan Chang, Kaohsiung City (TW); Chien-Chung Huang, Taichung Hsien (TW); Yen-Chu Chen, Nantou County (TW); Yi-Wei Chen, Taichung County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/850,506

(22) Filed: Sep. 5, 2007

(51) Int. Cl. H01L 21/477

(52) U.S. Cl. 438/664; 257/E21.497

(57) ABSTRACT

A method of forming an electrical connection structure is described. A dielectric layer is formed covering a first conductor on a substrate, and then an opening is formed in the dielectric layer exposing the first conductor. A first cleaning step is conducted using fluorine-containing plasma to clean the surfaces of the dielectric layer and the exposed first conductor, and then at least one low-temperature annealing step is conducted. A second cleaning step is conducted using argon plasma to clean the above surfaces. A second conductor is then formed in the opening.

### BACKGROUND OF THE INVENTION

1. Field of Invention

This invention relates to an integrated circuit (IC) fabricating process, and more particularly to a method of forming an electrical connection structure.

2. Description of Related Art

As the device dimension increasingly gets smaller, the aspect ratio of contact/via hole gradually becomes larger. To effectively remove the native oxide at the bottom of a contact/via hole before a metal barrier layer is formed therein, the substrate is much treated with argon plasma in the prior art.

However, overly argon-plasma treatment rounds the corner of a contact/via hole and may even cause connection of adjacent contact/via holes, which will cause bridging of the metal barrier layer that results in short of adjacent contacts.

Fluorine-containing gas has also been used to clean contact/via holes in the prior art. However, since the etching selectivity of fluorine-containing gas between silicon oxide and high-T silicon nitride layer is quite low, the contact/via hole is expanded altering the critical dimension, and it is even possible that the contact shorts with the gate when the contact etching stop layer includes silicon nitride. Moreover, the fluorine-containing plasma partially removes the silicon atoms in the metal silicide layer exposed in the contact/via hole so that the resistance of the metal silicide layer is raised.

Related patents/patent-publications concerning contact region cleaning include U.S. Pat. No. 5,043,299, U.S. Pat. No. 6,313,042, U.S. Pat. No. 5,620,925 and US 2007/0015360, for example.

U.S. Pat. No. 5,043,299 provides a selective W-deposition process done to a semiconductor wafer, which includes cleaning the wafer surface. The wafer is placed in a cleaning chamber under a certain pressure and then heated to 20-80° C. A gas mixture of H₂, BCl₃, SF₆ and NF₃ is introduced and made into plasma for 20-300 seconds. After the gas is closed, a non-reactive gas is introduced to remove the residue in the chamber.

U.S. Pat. No. 6,313,042 provides a contact cleaning method that uses fluorine-containing plasma to remove native oxide and then uses hydrogen-containing plasma to remove the residual fluorine. The document also mentions that it is not suitable to use fluorine-containing plasma and argon plasma in sequence to clean the contact regions.

U.S. Pat. No. 5,620,925 provides a semiconductor device process including a cleaning step using halogen-containing plasma. After the dielectric layer is etched using a halogen-containing plasma, such as chlorine- or fluorine-containing plasma, to expose contact regions, the dielectric layer and the contact regions are cleaned with inert-gas plasma, halogen-containing plasma and hydrogen-containing plasma in sequence.

US 2007/0015360 provides a contact cleaning method that uses remote fluorine-containing plasma to remove the oxidized regions of a metal silicide surface and then uses a silicon-containing compound to recover the metal silicide surface.

### SUMMARY OF THE INVENTION

This invention provides a method of forming an electrical connection structure, which includes cleaning steps capable of completely removing the native oxide in a contact/via hole, without causing barrier bridging due to corner rounding of contact/via holes, overly expansion of contact/via holes or raise in the electrical resistances of the salicide layers exposed in contact/via holes.

An embodiment of the method of forming an electrical connection structure of this invention is described as follows. A dielectric layer is formed covering a first conductor on a substrate. An opening is formed in the dielectric layer exposing the first conductor. A first cleaning step is conducted using fluorine-containing plasma to clean the surfaces of the dielectric layer and the exposed first conductor, and then at least one annealing step is conducted. After the at least one annealing step, a second cleaning step using argon plasma is conducted to clean the surfaces. A second conductor is then formed in the opening.

In an embodiment, the annealing step is for cleaning the substrate. The annealing step may be conducted at a temperature of about 100-200° C. The duration of the annealing step may be about 30-120 seconds. It is possible to conduct the annealing step in-situ in a chamber for conducting the first cleaning step.

In an embodiment, the annealing step is for lowering the electrical resistance of the first conductor. The annealing step may be conducted at a temperature of about 300-500° C. The duration of the annealing step may be about 30-120 seconds. It is possible that the annealing step is not conducted in a chamber for conducting the first cleaning step.

In an embodiment, the at least one annealing step includes a first annealing step for cleaning the substrate and a second annealing step for lowering the resistance of the first conductor. The first annealing step may be conducted before the second annealing step. The first annealing step may be conducted at a temperature lower than the one at which the second annealing step is conducted. The first and second annealing steps may be conducted in different chambers. The first annealing step may be conducted at a temperature of about 100-200° C. The duration of the first annealing step may be about 30-120 seconds. The first annealing step may be conducted in-situ in a chamber for conducting the first cleaning step. The second annealing step may be conducted at a temperature of about 300-500° C. The duration of the second annealing step may be about 30-120 seconds. It is possible that the second annealing step is not conducted in a chamber for conducting the first cleaning step or the second cleaning step.

The fluorine-containing plasma may be generated from a fluorine-containing gas or gas mixture that is selected from the group consisting of NF₃, NF₃/NH₃, NF₃/H₂, SF₆/H₂O, HF and combinations thereof. The first conductor may include nickel silicide, cobalt silicide or nickel platinum silicide.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a flow chart of a method of forming an electrical connection structure according to a first embodiment of this invention.

FIGS. 2A-2G depict, in a cross-sectional view, a process flow of a method of forming an electrical connection structure according to the first embodiment.

FIG. 3 is a flow chart of a method of forming an electrical connection structure according to a second embodiment of this invention.

FIGS. 4A-4G depict, in a cross-sectional view, a process flow of a method of forming an electrical connection structure according to the second embodiment.

### DESCRIPTION OF EMBODIMENTS

This invention will be further explained with the following embodiments, which are not intended to limit the scope of this invention.

### First Embodiment

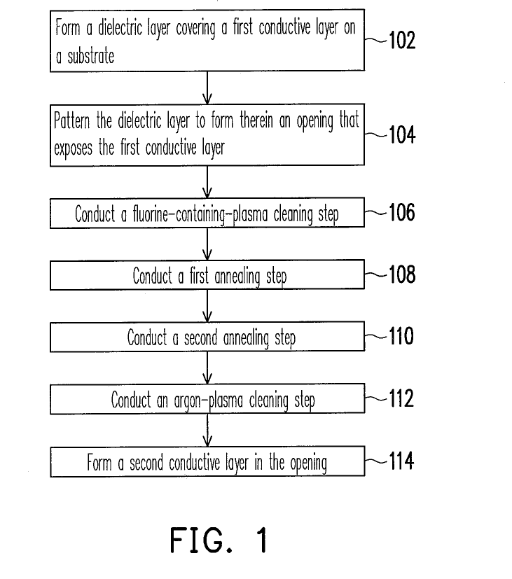

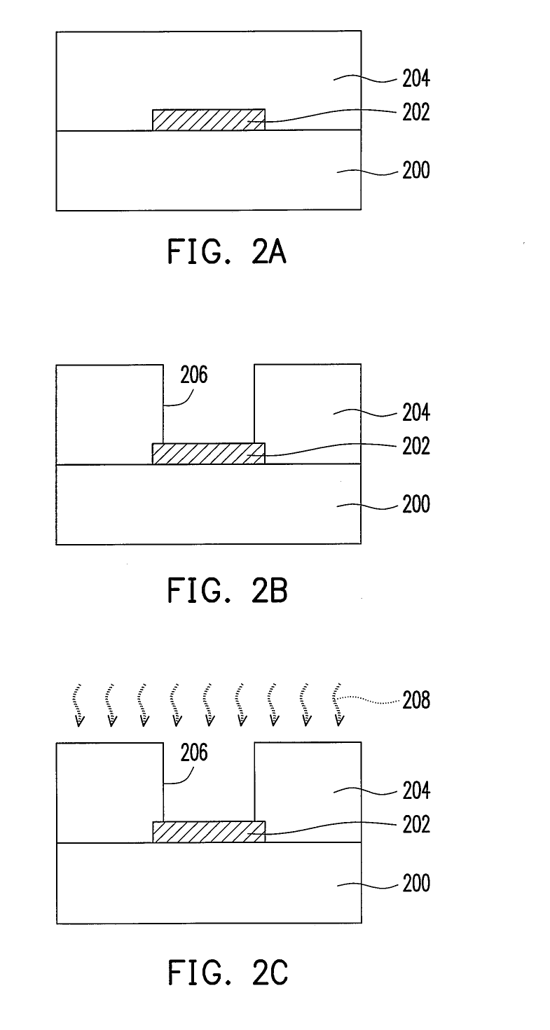

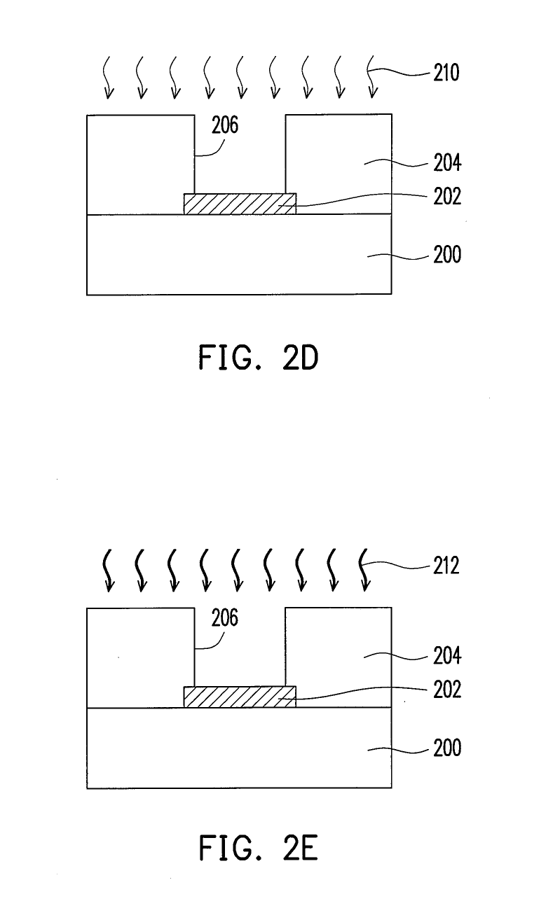

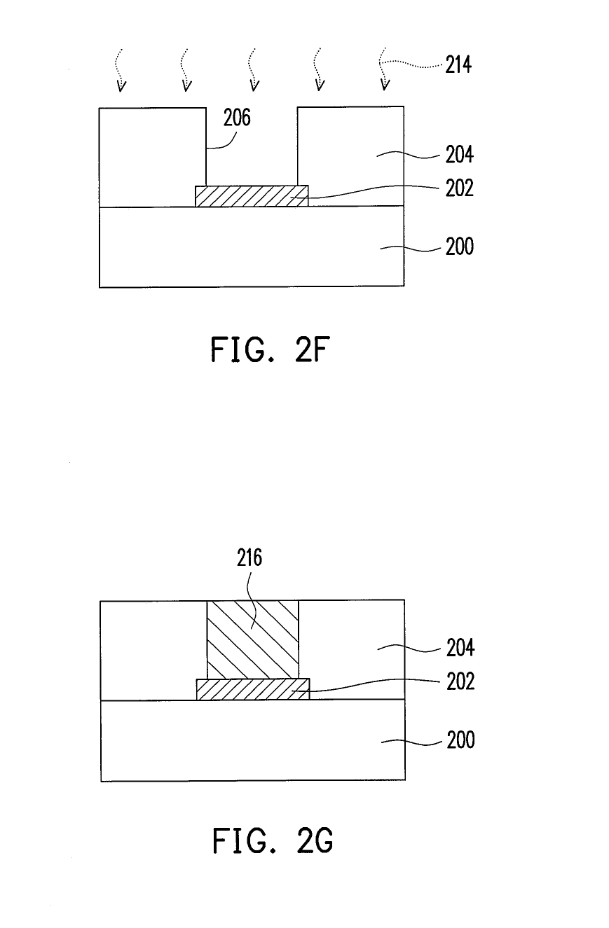

FIG. 1 is a flow chart of a method of forming an electrical connection structure according to the first embodiment of this invention. FIGS. 2A-2G depict, in a cross-sectional view, a process flow of a method of forming an electrical connection structure according to the first embodiment of this invention.

Referring to FIGS. 1 and 2A, in the step 102, a dielectric layer 204 is formed on the substrate 200, which may be a semiconductor substrate like a silicon substrate or a semiconductor compound substrate like a SiGe substrate. The substrate 200 has been formed with a conductor 202 thereon, which is then covered by the dielectric layer 204 and possibly includes aluminum, molybdenum, copper, tungsten, molybdenum silicide, tungsten silicide, titanium silicide, nickel silicide, cobalt silicide, nickel platinum silicide or titanium nitride. The dielectric layer 204 may include silicon oxide, silicon nitride, silicon oxide doped with boron and/or phosphorous, or a low-k material.

Referring to FIGS. 1 and 2B, in the step 104, the dielectric layer 204 is patterned to form an opening 206 that exposes the conductor 202. The patterning process may include forming a photoresist layer on the dielectric layer 204, transferring an opening pattern onto the photoresist layer with exposure and development, etching the dielectric layer 204 using the patterned photoresist layer as a mask and removing the patterned photoresist layer. The opening 206 may be a contact hole or a via hole.

Referring to FIGS. 1 and 2C, in the step 106, a fluorine-containing-plasma cleaning step 208 is conducted, capable of removing the native oxide formed on the conductor 202 after the opening 206 is formed. The fluorine-containing plasma may be generated from a fluorine-containing gas or gas mixture selected from the group consisting of NF₃, NF₃/NH₃, NF₃/H₂, SF₆/H₂O, HF and combinations thereof. The cleaning step 208 may be conducted at a temperature of about 20-60° C., under a pressure of 1.5-3 Torr and with an RF power of 10-50 W, for 1˜60 seconds.

Referring to FIGS. 1 and 2D, in the step 108, a first annealing step 210 is conducted in-situ in the same chamber for conducting the cleaning step 208. The first annealing step 210 may be conducted at a temperature of about 100-200° C. for about 30-120 seconds, capable of effectively removing the by-products produced in the cleaning step 208 to avoid problems caused by residue of the by-products.

Referring to FIGS. 1 and 2E, in the step 110, a second annealing step 212 is conducted, possibly not in the chamber for conducting the fluorine-containing-plasma cleaning step 208. The second annealing step 212 may be conducted at a temperature of 300-500° C., and the duration of the same may be 30-120 seconds. In a case where the conductor 202 includes a metal silicide, the silicon in the metal silicide is partially removed by the fluorine-containing plasma in the cleaning step 208 to raise the resistance of the conductor 202. The second annealing step 212 can convert the altered metal silicide to a phase having a lower resistance to lower the sheet resistance of the conductor 202.

Referring to FIGS. 1 and 2F, in the step 112, an Ar-plasma cleaning step 214 is conducted. The Ar-plasma cleaning step 214 may be conducted at a temperature of about 20-60° C., under a pressure of 0.1-0.2 mTorr and with an RF power of 100-300 W, for 1-60 seconds.

Referring to FIGS. 1 and 2G, in the step 114, the opening 206 is filled with another conductor 216, which includes a barrier layer possibly including titanium and/or titanium nitride, and a metal layer possibly including copper, tungsten or aluminum.

As mentioned above, the cleaning process after the formation of the opening includes a fluorine-containing-plasma cleaning step and an argon-plasma cleaning step. Since each cleaning step is conducted for a relatively short period, no barrier bridging is caused due to corner rounding of the contact/via holes and the holes are not expanded overly. In addition, the first annealing step conducted after the fluorine-containing-plasma cleaning step can effectively remove the by-products produced in the same cleaning step. The second annealing step can effectively lower the resistance of the conductor as a metal silicide layer exposed in the contact/via hole.

### Embodiment 2

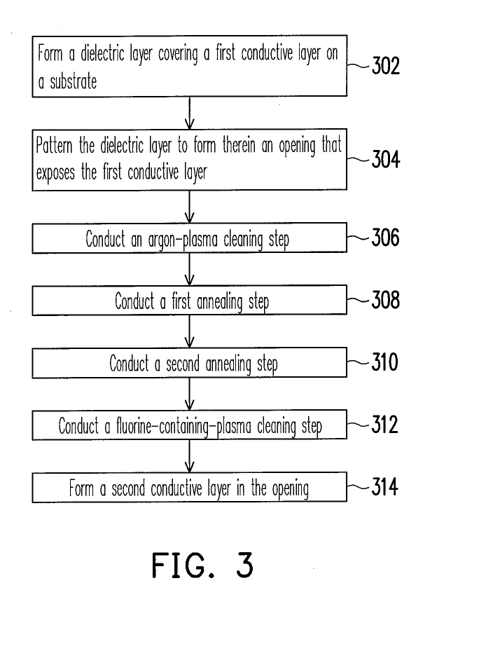

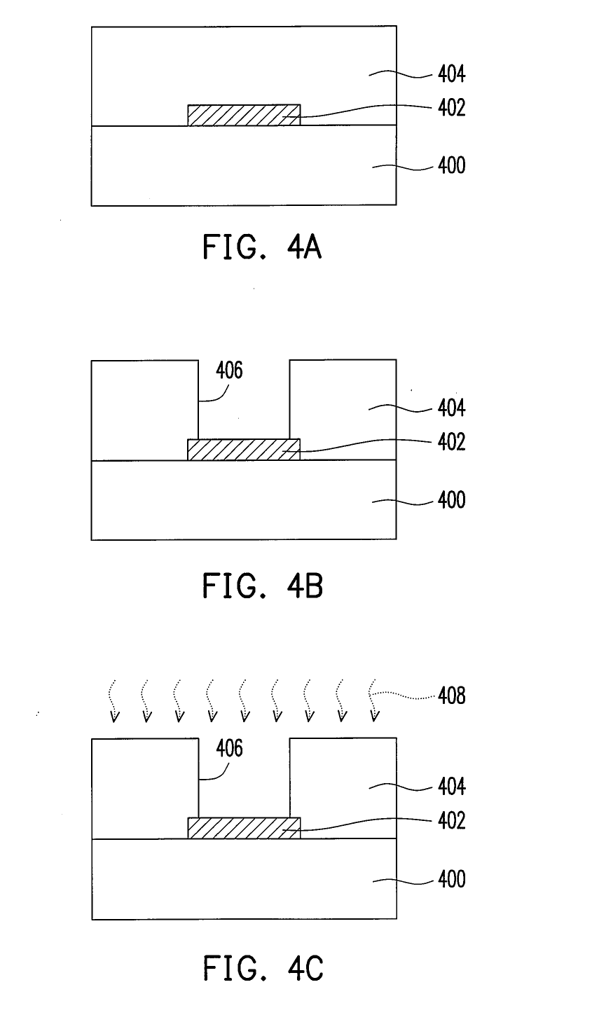

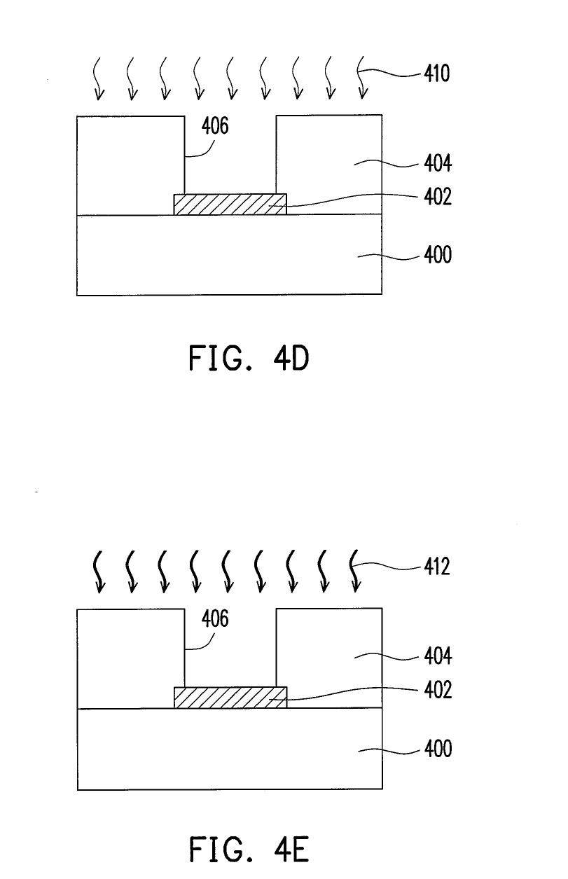

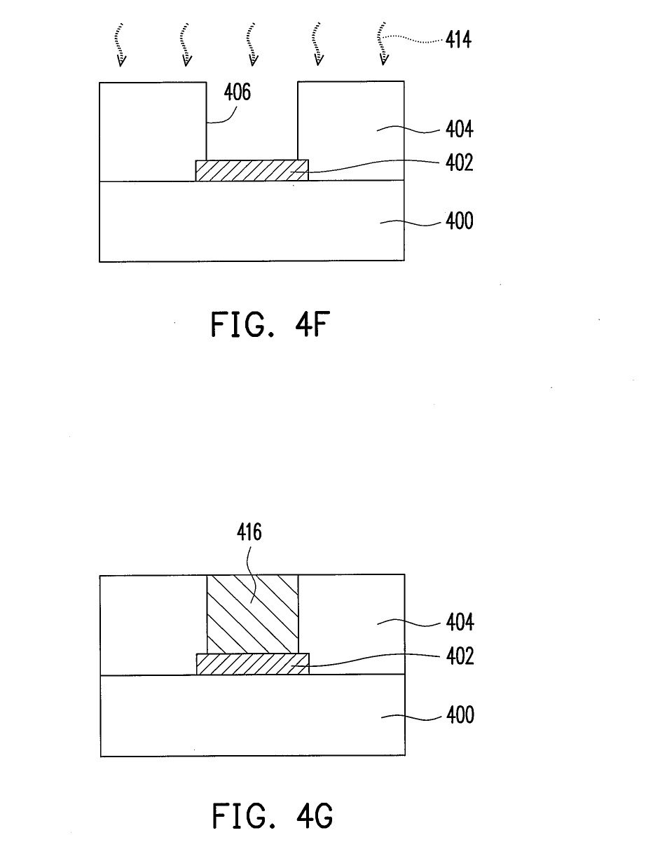

FIG. 3 is a flow chart of a method of forming an electrical connection structure according to the second embodiment of this invention. FIGS. 4A-4G depict, in a cross-sectional view, a process flow of a method of forming an electrical connection structure according to the second embodiment.

Referring to FIGS. 3 and 4A, in the step 302, a dielectric layer 404 is formed on the substrate 400, which may be a semiconductor substrate like a silicon substrate or a semiconductor compound substrate like a SiGe substrate. The substrate 400 has been formed with a conductor 402 thereon, which is then covered by the dielectric layer 404 and possibly includes aluminum, molybdenum, copper, tungsten, molybdenum silicide, tungsten silicide, titanium silicide, nickel silicide, cobalt silicide, nickel platinum silicide or titanium nitride. The dielectric layer 404 may include silicon oxide, silicon nitride, silicon oxide doped with boron and/or phosphorous, or a low-k material.

Referring to FIGS. 3 and 4B, in the step 304, the dielectric layer 404 is patterned to form an opening 406 that exposes the conductor 402. The patterning process may include forming a photoresist layer on the dielectric layer 404, transferring an opening pattern onto the photoresist layer with exposure and development, etching the dielectric layer 404 using the patterned photoresist layer as a mask and removing the patterned photoresist layer. The opening 406 may be a contact hole or a via hole.

Referring to FIGS. 3 and 4C, in the step 306, an Ar-plasma cleaning step 408 is conducted. The Ar-plasma cleaning step 408 may be conducted at a temperature of about 20-60° C., under a pressure of 0.1-0.2 mTorr and with an RF power of 100-300 W, for 1-60 seconds.

Referring to FIGS. 3 and 4D, in the step 308, a first annealing step 410 is conducted in-situ in the same chamber for conducting the Ar-plasma cleaning step 408. The first annealing step 410 may be conducted at a temperature of about 100-200° C. for about 30-120 seconds, capable of removing the impurities or particles produced in the Ar-plasma cleaning step 408 to avoid problems caused by residue of the same.

Referring to FIGS. 3 and 4E, in the step 310, a second annealing step 412 is conducted, possibly not in the chamber for conducting the Ar-plasma cleaning step 408. The second annealing step 412 may be conducted at a temperature of 300-500° C., and the duration of the same may be 30-120 seconds.

Referring to FIGS. 3 and 4F, in the step 312, a fluorine-containing-plasma cleaning step 414 is conducted, capable of removing the native oxide formed on the conductor 402 after the opening 406 is formed. The fluorine-containing plasma may be generated from a fluorine-containing gas or gas mixture selected from the group consisting of NF₃, NF₃/NH₃, NF₃/H₂, SF₆/H₂O, HF and combinations thereof. The cleaning step 414 may be conducted at a temperature of about 20-60° C., under a pressure of 1.5-3 Torr and with an RF power of 10-50 W, for 1˜60 seconds.

Referring to FIGS. 3 and 4G, in the step 314, the opening 406 is filled with another conductor 416, which includes a barrier layer possibly including titanium and/or titanium nitride, and a metal layer possibly including copper, tungsten or aluminum.

As mentioned above, the cleaning process after the formation of the opening includes an argon-plasma cleaning step and a fluorine-containing-plasma cleaning step. Since each cleaning step is conducted for a relatively short period, no barrier bridging is caused due to corner rounding of the contact/via holes and the holes are not expanded overly. In addition, the first annealing step conducted after the Ar-plasma cleaning step can effectively remove the particles or impurities produced in the same cleaning step. The second annealing step can effectively lower the resistance of the conductor as a metal silicide layer exposed in the contact/via hole.

This invention has been disclosed above in the preferred embodiments, but is not limited to those. It is known to persons skilled in the art that some modifications and innovations may be made without departing from the spirit and scope of this invention. Hence, the scope of the present invention should be defined by the following claims.

What is claimed is:

1. A method of forming an electrical connection structure, comprising:
forming a dielectric layer covering a first conductor on a substrate;
forming, in the dielectric layer, an opening that exposes the first conductor;
conducting a first cleaning step using fluorine-containing plasma to clean surfaces of the dielectric layer and the exposed first conductor;
conducting at least one annealing step after the first cleaning step;
conducting, after the at least one annealing step, a second cleaning step using argon plasma to clean the surfaces of the dielectric layer and the exposed first conductor; and
forming a second conductor in the opening.

2. The method of claim 1, wherein the annealing step is for cleaning the substrate.

3. The method of claim 2, wherein the annealing step is conducted at a temperature of about 100-200° C.

4. The method of claim 2, wherein the annealing step is conducted for about 30-120 seconds.

5. The method of claim 2, wherein the annealing step is conducted in-situ in a chamber for conducting the first cleaning step.

6. The method of claim 1, wherein the annealing step is for lowering an electrical resistance of the first conductor.

7. The method of claim 6, wherein the annealing step is conducted at a temperature of about 300-500° C.

8. The method of claim 6, wherein the annealing step is conducted for about 30-120 seconds.

9. The method of claim 6, wherein the annealing step is not conducted in a chamber for conducting the first cleaning step.

10. The method of claim 1, wherein the at least one annealing step comprises:
a first annealing step for cleaning the substrate; and
a second annealing step for lowering an electrical resistance of the first conductor.

11. The method of claim 10, wherein the first annealing step is conducted before the second annealing step.

12. The method of claim 11, wherein the first annealing step is conducted at a temperature lower than a temperature at which the second annealing step is conducted.

13. The method of claim 12, wherein the first and the second annealing steps are conducted in different chambers.

14. The method of claim 12, wherein the first annealing step is conducted at a temperature of about 100-200° C.

15. The method of claim 12, wherein first the annealing step is conducted for about 30-120 seconds.

16. The method of claim 12, wherein the first annealing step is conducted in-situ in a chamber for conducting the first cleaning step.

17. The method of claim 12, wherein the second annealing step is conducted at a temperature of about 300-500° C.

18. The method of claim 12, wherein the second annealing step is conducted for about 30-120 seconds.

19. The method of claim 12, wherein the second annealing step is not conducted in a chamber for conducting the first cleaning step or the second cleaning step.

20. The method of claim 1, wherein the fluorine-containing plasma is generated from a fluorine-containing gas or gas mixture that is selected from the group consisting of NF₃, NF₃/NH₃, NF₃/H₂, SF₆/H₂O, HF and combinations thereof.

21. The method of claim 1, wherein the first conductor comprises nickel silicide, cobalt silicide or nickel platinum silicide.
